(19) United States
(12) Patent Application Publication
(10) Pub. No.: US 2010/0023842 A1
(43) Pub. Date: Jan. 28, 2010

(54) MULTISEGMENT LOSS PROTECTION

(75) Inventors: Timothy J. Rahrer, Ottawa (CA); Emre Gunduzhan, Bethesda, MD (US); Martin Jan Soukup, Ottawa (CA)

Correspondence Address: WITHROW & TERRANOVA, P.L.L.C., 100 REGENCY FOREST DRIVE, SUITE 160, CARY, NC, 27518, US

(73) Assignee: NORTEL NETWORKS LIMITED, St. Laurent (CA)

(21) Appl. No.: 12/342,174

(22) Filed: Dec. 23, 2008

Related U.S. Application Data
(60) Provisional application No. 61/083,710, filed on Jul. 25, 2008.

(51) Int. Cl. H03M 13/05; G06F 11/10

(52) U.S. Cl. 714/776; 714/E11.032

(57) ABSTRACT

A method for providing error correction of media packets. Service nodes associated with a core network segment use a first error correction process, and service nodes associated with an access network segment use a second error correction process. Service nodes associated with a local network segment may use a third error correction process. The present invention utilizes different error correction processes on different network segments as appropriate. Service nodes may receive indicators from monitoring agents that error correction is insufficient and, in response, a service node may increase an amount of error correction associated with a network segment. Media packets may be interleaved in a forward error correction (FEC) block in a manner that increases an amount of packet recovery.

This application claims the benefit of U.S. provisional patent application Ser. No. 61/083,710 filed Jul. 25, 2008, the disclosure of which is incorporated herein by reference in its entirety.

### FIELD OF THE INVENTION

This invention relates generally to providing packetized video over a segmented network, and in particular to using error correction processes based on attributes of each network segment.

### BACKGROUND OF THE INVENTION

Video, such as a television broadcast or an on-demand program, is increasingly being delivered to subscribers in a packetized format over a video distribution network. Typically, digitized video is first packetized by encapsulating sequential units of the digitized video into a stream of Internet Protocol packets and then forwarded from a headend towards a premises, such as a residence or business. Packetized video offers many advantages over non-packetized video, including the ability to use emerging technologies, such as switched digital video, to allocate network bandwidth more efficiently than previously possible. However, service providers have discovered that reliably delivering a consistent stream of packetized video to an end-user over a network that may span hundreds of miles is a challenging proposition. Each packet must traverse multiple network segments coupled together by different types of equipment that may operate in different energy domains, such as optical or electrical. Each packet faces potential disruption along the way from cable cuts, equipment failure, transient noise, and congested network nodes. Once the packet reaches the destination premises, the packet must be carried over a local area network that can vary widely from premises to premises, that the service provider may have little knowledge of or control over, and that may change at the whim of the end-user. The packets are ultimately delivered to a device, such as a set top box or a computer, for display on a monitor, such as a television or liquid crystal display (LCD) computer screen.

Video distribution networks can generally be described as having three network segments: a core network segment that extends from a super headend to a regional video serving office, an access network segment that extends from the regional video serving office to a premises, and a local network segment that carries video packets within a premises. Each network segment has different attributes and presents unique challenges relating to the delivery of packetized video. The core network segment is typically a fiber network and may have a high amount of bandwidth. The access network segment may be an xDSL network and may have very limited bandwidth. A local network segment in one premises may use a wired Ethernet technology and have high robustness, while a local network segment in an adjacent premises may use a wireless technology and have low robustness and high susceptibility to interference.

Service providers have found that capital expenditure costs associated with initial configuration of a home network for packetized video service can be significant. Similarly, service providers have found that operating expenditures associated with service calls to debug and resolve problems in home networks can be quite significant. Many of the problems associated with delivering packetized video to a premises relates to video quality at the end-user device due to lost packets that may be the result of a severed cable, transient noise, and the like. Packet error correction technologies, such as forward error correction (FEC) or automatic repeat request (ARQ), may be used to prevent certain instances of packet loss from affecting video display quality. Where FEC is used, FEC is typically provided from a headend of the service provider all the way to a set top box in a premises, and the amount of FEC used is limited by the most bandwidth-constrained segment of the network. Consequently, while FEC may, for example, be sufficient to correct a majority of packet losses that may occur in an access segment of the network, FEC may be insufficient to correct packet losses that may occur in the core or local segments of the network. Moreover, the amount of FEC necessary to correct video quality problems occurring in a local network segment in one premises may be insufficient to correct video quality problems occurring in a local network segment of another premises.

ARQ can be useful when used in the access network segment or the local network segment, but is typically not used in the core network segment because of the amount of storage and processing that would be necessary to implement ARQ in a core network segment. Consequently, a service provider implementing ARQ may not provide any error correction for the core network segment. Therefore, it would be beneficial for a service provider to provide different error correction processes for different network segments based on the loss profile and bandwidth of the particular network segment. Further, it would be beneficial for a network provider to dynamically alter the error correction process used on a network segment in response to feedback regarding real-time error conditions associated with the network segment.

### SUMMARY OF THE INVENTION

The present invention implements different error correction processes, sometimes referred to as loss mitigation processes, in different segments of a network coupled together by service nodes. The error correction processes can include forward error correction (FEC), automatic repeat request (ARQ), call admission control (CAC), any other suitable mechanism adapted to prevent or correct packet loss, and any combination thereof. The present invention implements an appropriate error correction process based on bandwidth associated with the respective network segment and types of errors typically or actually experienced by the respective network segment. A service node may receive packets via a first network segment, use a first error correction process to recover lost or corrupted packets, and forward the packets via a second network segment to a service node that uses a second error correction process to recover lost or corrupted packets.

According to one embodiment of the invention, monitoring agents in one or more service nodes monitor error conditions on an associated network segment and communicate with an upstream error correction controller (ECC) to dynamically modify the amount or type of error correction being used for the associated network segment. The error correction processes associated with two different network segments can be different error correction processes, such as FEC and ARQ, or can be different types of error correction processes that use the same type of error correction, such as FEC, but use different amounts of error correction. For example, a service node associated with a core network segment may use an amount of FEC suitable for protecting a first number of lost packets that might be lost on the core network segment, and a service node associated with an access network segment may use an amount of FEC suitable for protecting a second, and smaller, number of lost packets since the access network segment may have significantly less bandwidth than the core network segment.

According to one embodiment of the invention, a service node associated with a core network segment uses a sufficient number of FEC packets suitable to protect a relatively large number of video packets that may be lost during a 50 milliseconds (ms)-100 ms protection switch event on the core network segment, such as re-routing traffic around a severed fiber cable. A service node associated with the access network segment uses a smaller number of FEC packets suitable to protect a relatively small number of video packets that may be lost during a short duration impulse loss on the access network segment, such as caused by transient noise. The FEC packets used on the access network segment are a subset of the FEC packets received via the core network segment. The present invention enables the reuse of FEC packets to tailor FEC for a particular network segment without the overhead required to recalculate FEC packets.

Those skilled in the art will appreciate the scope of the present invention and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the invention, and together with the description serve to explain the principles of the invention.

FIG. 1 is a block diagram of a switched digital media network according to one embodiment of the present invention.

FIG. 2 is a block diagram of a premises according to one embodiment of the present invention.

FIG. 3 is a block diagram of service nodes implementing error correction according to one embodiment of the present invention.

FIG. 4 is a flowchart illustrating a process for implementing error correction at a headend service node in a switched digital media network according to one embodiment of the present invention.

FIG. 5 is a flowchart illustrating error correcting processing at a service node according to one embodiment of the present invention.

FIG. 6 is a flowchart illustrating error correcting processing at a service node according to another embodiment of the present invention.

FIG. 7 is a block diagram of service nodes implementing monitoring agents according to one embodiment of the present invention.

FIG. 8 is a flowchart illustrating altering an error correction process in response to feedback relating to a changed loss profile associated with a network segment.

FIG. 9 is a block diagram of a forward error correction (FEC) block according to one embodiment of the present invention.

FIG. 10 is a block diagram showing a loss of sequential packets from a FEC block transmitted in interleaved order as illustrated in FIG. 9.

FIG. 11 is a block diagram of a FEC block according to another embodiment of the present invention.

FIG. 12 is a block diagram of a service node according to one embodiment of the present invention.

FIG. 13 is a block diagram of a customer premises equipment (CPE) according to one embodiment of the present invention.

### DETAILED DESCRIPTION OF THE PREFERRED EMBODIMENTS

The embodiments set forth below represent the necessary information to enable those skilled in the art to practice the invention and illustrate the best mode of practicing the invention. Upon reading the following description in light of the accompanying drawing figures, those skilled in the art will understand the concepts of the invention and will recognize applications of these concepts not particularly addressed herein. It should be understood that these concepts and applications fall within the scope of the disclosure and the accompanying claims.

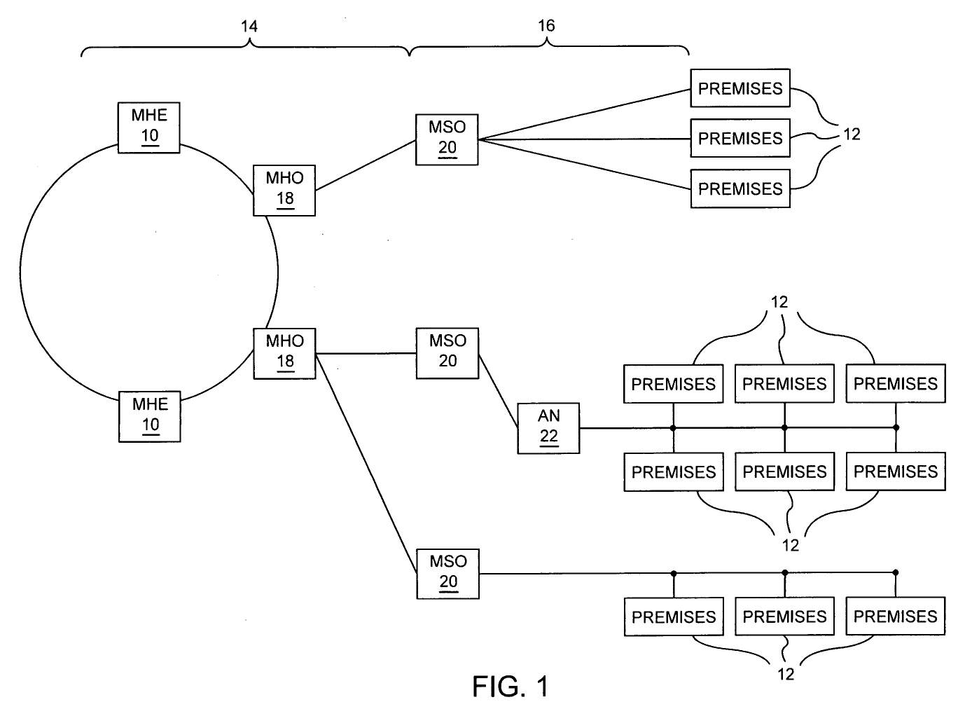

Switched digital media networks allow delivery of streaming media in the form of media streams for various channels, or on-demand programs, which can be selected by customers for listening or viewing. Switched digital media networks may represent satellite, cable, internet protocol television (IPTV), or like networks used to deliver audio or video for a public or private setting. Typically, service providers rely on an extensive and hierarchical network, which branches out from a centralized location where media content is aggregated and extends to a customer premises through various intermediate networks. An exemplary but simplistic switched digital media network is illustrated in FIG. 1. The centralized location where media is aggregated resides in a service node such as a media head end (MHE) 10, which is configured to deliver the various media streams for the corresponding channels to premises 12 through core network segments 14 and access network segments 16. The access network segments 16 provide wired or wireless access to the premises 12 and the core network segments 14 represent the primary transport networks that connect the various access network segments 16 to the MHE 10.

The MHE 10, such as a super head end for video, will generally have access to various satellite dish farms, media servers, encoders, or the like, which provide various media content for corresponding channels to the MHE 10. While for purposes of illustration the MHE 10 is depicted as a single entity, the MHE 10 may comprise a number of pieces of equipment to accomplish the required functions of the MHE 10, including content management, content encoding, the provision of video on demand services, and the like. The MHE 10 aggregates the media content from the various sources and allocates the media content for delivery toward the premises 12 at the appropriate time and on the appropriate channel. Notably, the media content may be delivered to the premises 12 according to a predefined schedule or in response to a customer request, as is provided for video on demand services. Notably, the media content may include advertising content, which is slotted into appropriate slots within the media content. In video or television based switched digital media networks, the advertising content provided by the MHE 10 is generally national advertising intended for delivery to customers over a wide geographic area. A switched digital media network may have multiple MHEs 10 for purposes of redundancy, as illustrated by the two MHEs 10 as shown in FIG. 1.

Media content delivered toward one or more premises 12 may pass through a media hub office (MHO) 18, which resides in the core network segment 14. Although not required, a single MHO 18 may be allocated to a single city or metro area. The MHO 18 may have access to local media content, including local advertising, which may be provided in association with the media content being provided by the MHE 10. In addition to providing local advertising, local emergency alert messages or content may be injected into the media content at the MHOs 18. Both the MHE 10 and the MHOs 18 may provide various types of encoding and decoding as well as transcoding to effectively change encoding, compression, and formatting associated with the media content being delivered toward the customer premises 12.

The next service node in the path towards the customer premises 12 may include a media serving office (MSO) 20, which generally resides in the city or metro area being served by the MSO 20. Further, the MSOs 20 may be distributed throughout the corresponding geographic location, such as in association with one or more neighborhoods. Within each of these neighborhoods or corresponding areas, each MSO 20 may be associated with one or more access nodes (AN) 22, which may also be referred to as access multiplexers. These access nodes 22 effectively aggregate all of the wired or wireless connections between the various premises 12. The MSO 20 and the access node 22 are generally associated with the corresponding access network segment 16. As illustrated, a single access node 22 may serve any number of premises 12. Exemplary access network segments 16 include digital subscriber lines (DSL), passive optical networks (PON), Ethernet networks, cellular networks, broadband wireless networks such as a WiMAX network, and the like. The access nodes 22 may include digital subscriber line access multiplexers (DSLAMs), optical line terminals (OLT), Ethernet modems, cellular base stations, wireless access points, and the like. Notably, if a distance between a MSO 20 and a premises 12 is sufficiently small, an access node 22 may not be required or desired to serve a premises 12, and one or more premises 12 may be served directly by a MSO 20.

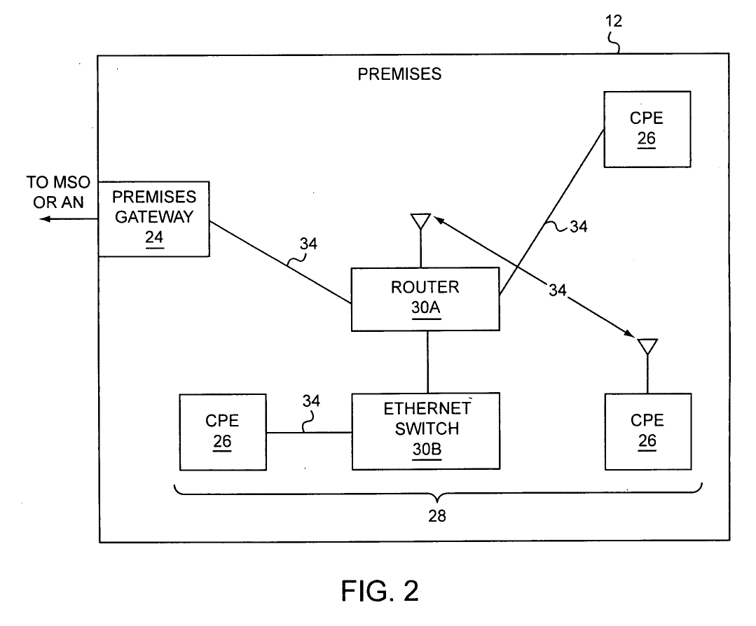

Once inside the premises 12, the media content may be delivered to any number of devices, as illustrated in FIG. 2. Notably, the customer premises 12 may, but need not, include a premises gateway (PG) 24, such as a residential gateway, that provides a gateway function between the access network segment 16 and any customer premises equipment (CPE) 26, such as a set top box (STB), a personal video recorder (PVR), a personal computer (PC), a telephone, or the like. The PG 24 may be coupled to the CPE 26 via a local network segment 28, which may include one or more switching devices 30 such as a router 30A and an Ethernet switch 30B. The PG 24 may be implemented as a stand-alone device, or can be integrated into another network element, such as a cable or DSL modem. Communications links 34 used in the local network segment 28 may comprise any conventional or proprietary network technologies, including wireless such as WiFi, data over coaxial cable, Ethernet over various physical media such as Category 5 cable or phone lines, and the like, and each communications link 34 may have a different bandwidth and robustness than another communications link 34. Notably, FIG. 2 is used to illustrate that the local network segment 28 may take various forms and may include various types of communications links 34, CPEs 26, and switching devices 30.

Lost, damaged, or delayed media packets in any of the network segments 14, 16, 28 can result in noticeable audio or video aberrations at the CPE 26. Moreover, each network segment typically has a separate and different loss profile that characterizes the type of packet losses that may occur or typically occur on the respective network segment. For example, packet losses on the core network segment 14 due to interference are relatively rare. However, the type of event that may cause a packet loss on the core network segment 14, such as a severed cable or network element failure, may result in a relatively large number of lost packets, and may impact all premises 12 served by the service provider. In contrast, a typical loss profile for an access network segment 16 may include more frequent problems, such as transient impulse noise or crosstalk, that likely result in fewer lost packets than that caused by a severed cable, but that affect fewer premises 12 than a cable cut on the core network segment 14. Particularly challenging for a service provider are the local network segments 28, which differ from one premises 12 to another premises 12, each of which may involve myriad different switching devices 30, CPEs 26, and communications links 34, and whose configuration may change at the whim of the customer with no advance warning to the service provider. The net result of the variable and changing dynamic of the local network segment 28 is that service providers incur significant expenses setting up media services for a premises 12 and maintaining media quality in the premises 12 on an ongoing basis.

Some service providers attempt to diminish the impact of lost packets through mechanisms such as error correction. Error correction typically involves a tradeoff between bandwidth and delay. Some error correction techniques, such as forward error correction (FEC), utilize additional bandwidth by including additional information among media packets that can be used to recreate lost or corrupted media packets without waiting for a retransmission of the lost media packets. Other error correction techniques, such as automatic repeat request (ARQ), rely on retransmission of lost or corrupted media packets, which reduces bandwidth overhead but increases delay and increases storage requirements for storage of the media packets in the event a retransmission is required.

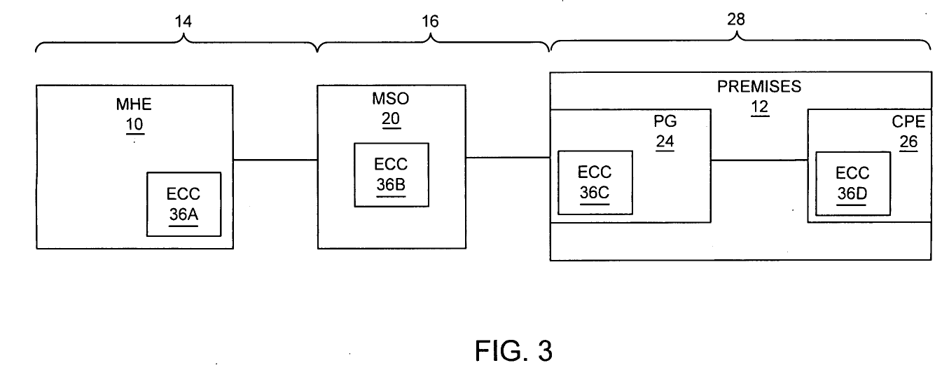

FIG. 3 is a block diagram of a respective path through a switched digital media network from a MHE 10 to a premises 12 according to one embodiment of the invention. For purposes of illustration, certain service nodes that may be used in one or more network segments, such as an MHO 18 in the core network segment 14 or an access node 22 in the access network segment 16, are omitted from FIG. 3. To reduce or eliminate video or audio aberrations associated with lost or corrupted media packets, one or more error correction controllers (ECCs) 36A-36D implement error correction processes at a respective service node, such as the MHE 10, the MSO 20, the PG 24, and the CPE 26. According to one embodiment of the invention, error correction processes may differ at each respective service node. For example, the MHE 10 may implement a FEC process using a particular size FEC block of media packets and both row and column FEC packets to ensure sufficient media packets can be recovered by a MSO 20 in the event of a cable cut or similar event. While such FEC processes may require substantial bandwidth, the core network segment 14 may comprise a fiber network that has excess bandwidth and thus the capability to enable such FEC processes.

In contrast to the MHE 10, the MSO 20 may be coupled to an access network segment 16 that has very limited bandwidth, such as an xDSL communications path, and that has insufficient excess bandwidth to provide a similar FEC block size and both row and column FEC packets. The MSO 20 may therefore alter the FEC block size and generate only column FEC packets to significantly reduce the amount of bandwidth required to implement FEC on the access network segment 16. While the different FEC block size and fewer FEC packets reduces the number of lost media packets that may be recovered, such a tradeoff provides sufficient reliability in view of the actual loss profile for the access network segment 16, which differs from the loss profile of the core network segment 14.

The PG 24 may be coupled to a local network segment 28 that has high bandwidth communications links 34, but which suffers significant media data packet loss due to interference with wireless or other electronic devices in the premises 12. The PG 24 therefore alters the FEC encoding to better suit the loss profile associated with the local network segment 28, such as by altering the FEC block size and generating both row and column FEC packets to enable the CPE 26 to recover a substantial number of media packets that may be lost en route from the PG 24 to the CPE 26.

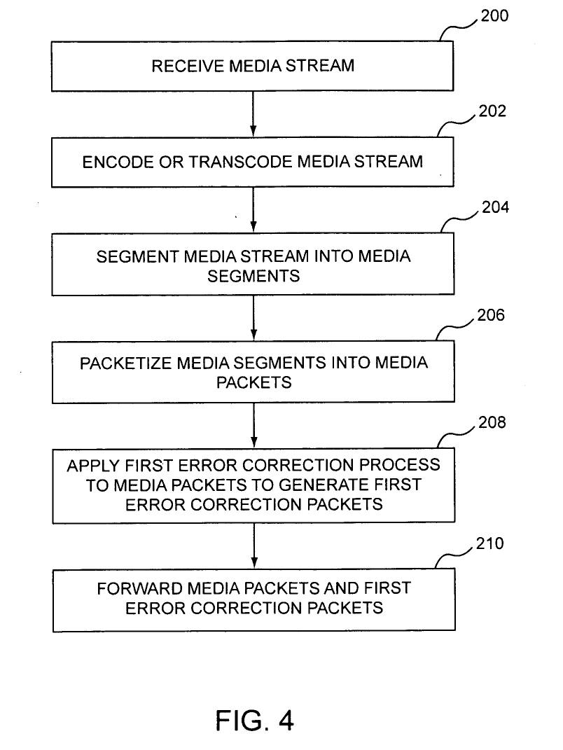

FIG. 4 is a flowchart illustrating error correction processing that may occur in a MHE 10 according to one embodiment of the invention. The MHE 10 receives a stream of media, such as a broadcast television channel, from a broadcast feed (step 200). The media stream may be in an analog or a digital format. If analog, the MHE 10 may digitize and encode the media stream into any suitable format suitable for delivering the media over the digital switched media network, such as Moving Pictures Experts Group-2 (MPEG-2) or MPEG-4. If the media stream is already digitized, the MHE 10 may transcode the media stream into a desired bit rate or format (step 202). The encoded media stream is then segmented into media segments (step 204). Segmentation may comprise any suitable grouping of digitized media units, and may differ based on the digital encoding used, as is understood by those skilled in the art. For example, if the encoding format is MPEG-2, the media segments may comprise one or more Transport Stream packets. If the encoding is MPEG-4, the media segments may comprise one or more Network Abstraction Layer units.

The media segments are then packetized into a suitable transport packet, such as a Real-time Transport Protocol (RTP) packet (step 206). It will be assumed for purposes of illustration that an FEC error correction process will be utilized for the core network segment 14. A desired first FEC error correction process is then applied to the media packets to generate a plurality of error correction packets (step 208). As is known to those skilled in the art, FEC error correction typically involves forming a two-dimensional block, or matrix, of a desired size of media packets that are to be protected, and then generating FEC packets that can be used to recreate one or more of the media packets if such media packets are lost or corrupted in transit through a network. Assume that the MHE 10 is coupled to a core network segment 14 that is a fiber network segment and has some excess bandwidth capacity. Further assume that the core network segment 14 may, from time to time, be impacted by a network element failure or cable cut that might occur, for example, during construction of a new office building miles away from the MHE 10. Also assume that a redundant MHE 10 or network routing path requiring 50 milliseconds (ms) to switchover to assume the responsibilities of the first MHE 10 or route around the failed network element is coupled to the core network segment 14, and during a 50 ms timeframe, as many as 16 media packets per channel may be lost for a 2 megabits per second (Mbps) video data stream. Thus, the MHE 10 may select a FEC block size and generate sufficient FEC packets to enable the recovery of up to 16 media packets so that media packets that are lost during the switchover can be recovered by the downstream MHE 10 without disrupting the presentation of the media on a CPE 26. The media packets and the FEC packets are then transmitted over the core network segment 14 (step 210). The FEC packets may be transmitted in line, intermixed with the media packets, or may be transmitted via a separate channel or port.

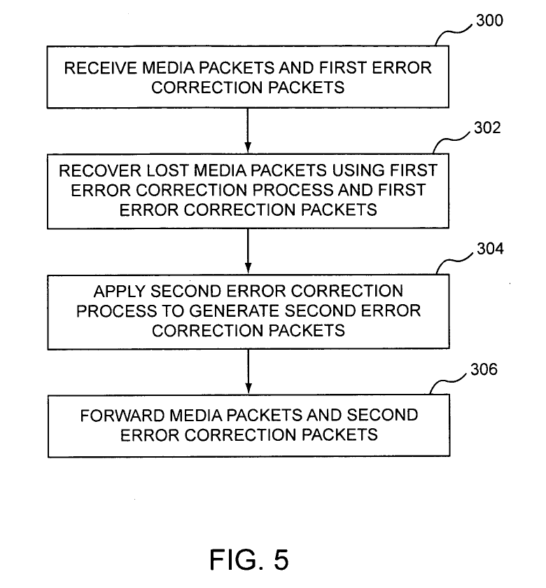

FIG. 5 is a flow diagram illustrating error correcting processing at the MSO 20 according to one embodiment of the invention. The MSO 20 receives the media packets and FEC packets sent from the MHE 10 (step 300). The MSO 20 may apply a first FEC process on the media packets to recover any media packets that may have been lost as the result of a cable cut or other disruption (step 302). Assume that the MSO 20 is coupled to an access network segment 16 that comprises an xDSL communications link and is bandwidth limited. Moreover, the loss profile for the access network segment 16 may mainly comprise transient impulse noise events that typically result in fewer than five lost packets per loss event. The MSO 20 may apply a second FEC process using a second FEC block size that is different from the FEC block size used by the MHE 10, and generate fewer FEC packets than generated by the MHE 10 such that the FEC process is suited to recovering only up to five lost packets per FEC block (step 304), but requiring less additional bandwidth for the error correction packets. The MSO 20 then transmits the media packets and FEC packets over the access network segment 16 (step 306).

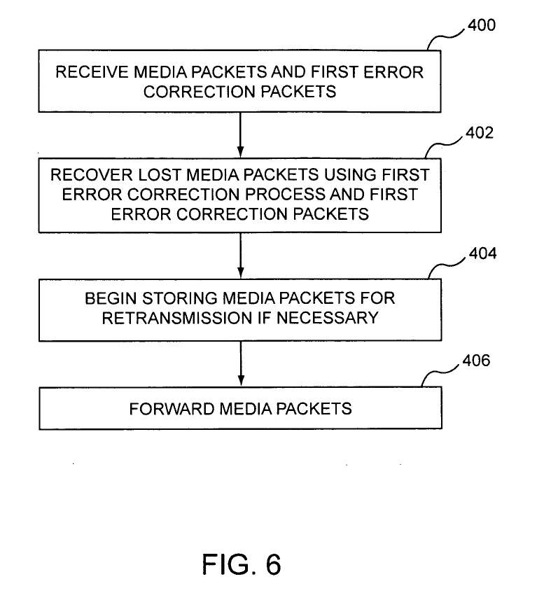

FIG. 6 is a flow diagram illustrating error correcting processing at the MSO 20 according to another embodiment of the invention. As discussed with respect to FIG. 5, the MSO 20 receives a plurality of media packets and FEC packets (step 400) and recovers any packets that were lost using the FEC process and the FEC packets (step 402). However, assume in this embodiment that the MSO 20 uses an ARQ error correction process in conjunction with the access network segment 16. The ARQ process initially stores the media packets in a local storage device prior to sending the media packets to the PG 24 (step 404). The ARQ process then forwards the media packets to the PG 24 (step 406). If the PG 24 acknowledges receipt of the media packets, the ARQ process can remove or overwrite the media packets in the local storage device. Otherwise, the ARQ process will retransmit the media packets until an acknowledgment is received from the PG 24. Alternatively the ARQ process may use a circular buffer of length sufficient to cover typical loss profiles and to respond to requests from the PG 24 for retransmission of specific lost packets. In yet another embodiment, the ARQ process may be implemented between the MSO 20 and the CPE 26 rather than the MSO 20 and the PG 24.

While ARQ requires less bandwidth than an FEC error correction process if no packet loss occurs, ARQ can introduce significant delay associated with retransmissions. Moreover, ARQ may not be suitable in some network segments where requests for retransmissions after a substantial packet loss event may overwhelm the capability of the sending service node to service the retransmission requests, or where the amount of processing and storage required to store the media packets requires excessive resources. For example, an ARQ error correction process may not be an appropriate error correction process for the core network segment 14 due to the significant amount of media packets being sent over the core network segment 14, and the large number of retransmission requests that would need to be serviced in the event of a packet loss event such as a cable cut.

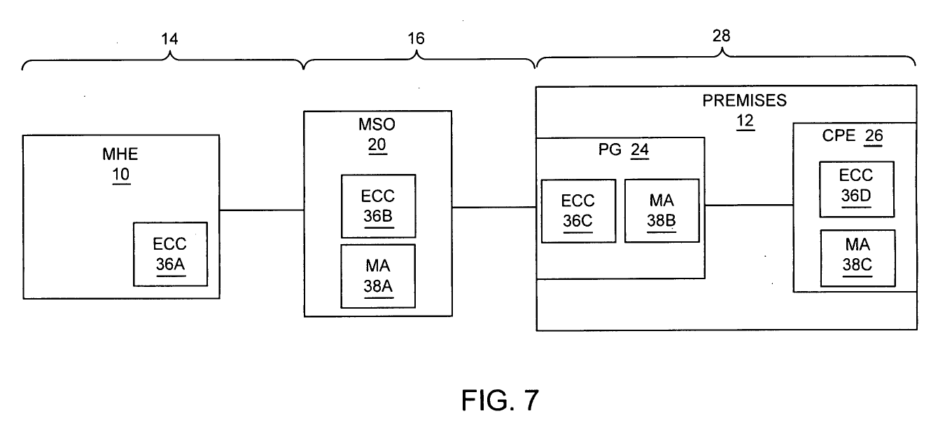

Referring now to FIG. 7, a block diagram of the service nodes illustrated in FIG. 3 is shown. One or more of the service nodes, such as the MSO 20, the PG 24, and the CPE 26, may include a monitoring agent (MA) 38 capable of monitoring the respective network segment to which the service node is coupled, and determine a loss profile associated with the particular network segment. The MAs 38 can provide information or requests to an upstream ECC 36 to dynamically alter an error correction process used to recover packets lost over the respective network segment. A monitoring agent suitable for use in the present invention is described in U.S. patent application Ser. No. 11/961,879 filed Dec. 20, 2007, entitled “MEDIA MONITORING,” the disclosure of which is hereby incorporated herein by reference in its entirety.

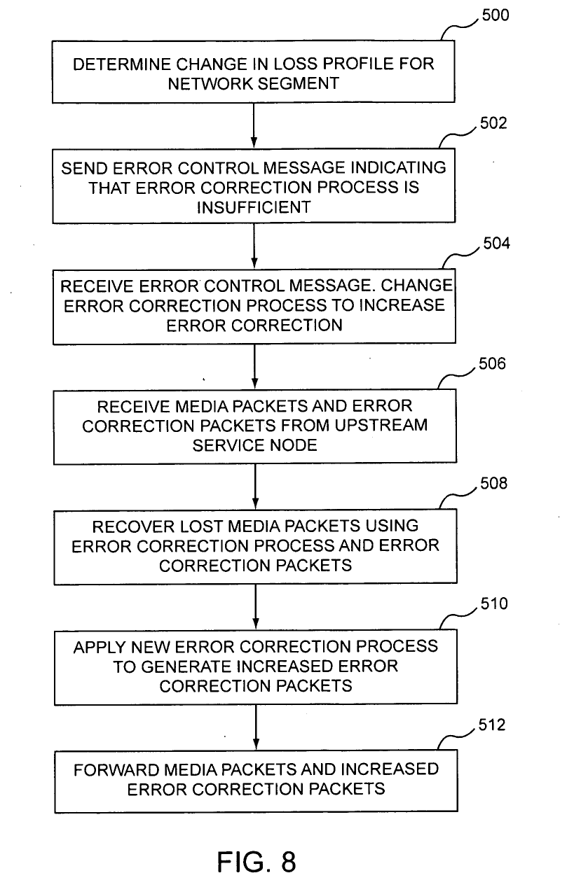

FIG. 8 is a flowchart illustrating a process for altering an error control process on a network segment according to one embodiment of the invention. For purposes of illustration, FIG. 8 will be discussed in conjunction with FIG. 7. Assume that the PG 24 uses a first FEC process that provides sufficient error correction for the CPE 26 to recover lost data packets sent by the PG 24 given the loss profile of the local network segment 28 at a particular time. Assume further that an event occurs that changes the loss profile of the local network segment 28. Assume, for example, that a customer reconfigures a switching device 30 in a way that increases dropped packets on the local network segment 28, or moves a large electronic device, such as a microwave oven, in proximity to a communications link 34, and the electromagnetic field generated by the microwave oven causes an increase in transient packet losses. Consequently, the first FEC process used by the PG 24 and the CPE 26 may now be insufficient to compensate for the greater number of lost packets given the new loss profile for the local network segment 28. The MA 38C determines that the loss profile for the local network segment 28 has changed (step 500). For example, the MA 38C may determine that in a significant number of transmissions the FEC packets are insufficient to recover all the packets that were lost. The MA 38C may provide an error control message to an upstream ECC 36, such as the ECC 36C associated with the PG 24, informing the ECC 36C that the existing error correction process is insufficient (step 502). The error control message could be a request for an increased number of FEC packets, data identifying the loss profile, or any other message capable of apprising the PG 24 that a new error correction process providing increased error protection is required to maintain a suitable media presentation quality.

In response to receiving the error control message, the ECC 36C can initiate a different error control process on subsequently received media packets that provides additional error correction beyond what had previously been provided by the ECC 36C, assuming that the communications links 34 between the PG 24 and the CPE 26 have sufficient bandwidth (step 504). Assume that the PG 24 receives a plurality of media packets from the MSO 20 via the access network segment 16 destined for the CPE 26 (step 506). The ECC 36C performs error correction on the media packets according to the error correction process associated with the network segment 16 (step 178). Prior to receiving the error control message from the CPE 26, the ECC 36C might have provided media packets in a particular FEC block size and with sufficient FEC packets to enable recovery of up to five sequential lost packets. The ECC 36C now alters the FEC block size and generates a larger number of FEC packets from the media packets to enable recovery of up to ten sequential lost packets by the CPE 26 (step 510). The PG 24 sends the plurality of media packets to the CPE 26 using the new FEC block size and the increased number of FEC packets (step 512). This process may be repeated until the level of error control processing provided by the ECC 36C is sufficient to provide the appropriate media presentation quality at the CPE 26. Notably, the error control modifications did not involve any additional processing by upstream service nodes or any additional bandwidth of an upstream network segment 14 or 16. Also notably, problems in video transmission were automatically monitored and corrected without manual intervention by service provider personnel, thereby eliminating associated call center and truck-roll support costs.

According to one embodiment of the invention, a service node can implement a first FEC error correction process on a first network segment, and a second FEC error correction process on a second network segment without having to regenerate FEC packets received via the first network segment. The present invention enables a processing node to easily reduce bandwidth used for error correction processing without expending resources recalculating new FEC packets. The present invention uses a Pro-MPEG Forum Code of Practice (COP) #3 FEC process as described in Society of Motion Picture and Television Engineers (SMPTE) Standards SMPTE 2002-1 and SMPTE 2022-1, both of which are hereby incorporated herein in their entirety. Pro-MPEG FEC involves generating an FEC matrix having a number of columns, referred to as the “L” dimension of the matrix, and having a number of rows, referred to as the “D” dimension of the matrix. The dimensions of a FEC matrix will be described herein with reference first to the L dimension (number of columns) and then to the D dimension (number of rows). For example, an FEC matrix having five columns and ten rows will be referred to herein as a 10 (L)×5 (D) FEC matrix. Error correction is provided in the form of FEC packets that are derived based on the media packets in a particular row or column of the FEC matrix. FEC packets that are generated to correct packet loss associated with a particular row will be referred to herein as row FEC packets. FEC packets that are generated to correct packet loss associated with a particular column will be referred to herein as column FEC packets. A relatively high amount of error correction may be provided by generating both row and column FEC packets. A lesser amount of error correction may be provided by generating only column FEC packets. As is understood by those skilled in the art, the size of an FEC matrix, and the use of row and column FEC packets, is a tradeoff between an amount of error correction desired versus an amount of bandwidth utilized. A higher ratio of FEC packets to media packets increases possible error correction, but similarly increases the bandwidth required to communicate the media packets and FEC packets. The phrase “FEC matrix” will be used herein to refer to a respective matrix of media packets. The phrase “FEC block” will be used herein to refer to both a respective FEC matrix and the FEC packets that are generated based on the FEC matrix.

Events that result in lost packets, such as a cable cut on a core network segment 14 or an impulse noise on an access network segment 16, typically result in a series of sequential packets being lost, rather than a plurality of random packets throughout an FEC block of packets. If only column FEC packets are generated for error correction, a number equal to L lost sequential packets may be recovered from an FEC block, assuming that the lost sequential packets are the only lost packets in the FEC block. If both row and column FEC packets are generated for error correction, a number equal to L+1 lost sequential packets may be recovered from an FEC block, again assuming that those packets are the only lost packets in the FEC block.

The present invention interleaves transmission of an FEC block of media packets and FEC packets in a manner that increases the number of sequential packets that may be recovered without the need to generate additional FEC packets. The present invention also enables reuse of a proper subset of the FEC packets for subsequent error correction on a second network segment without the need to regenerate FEC packets even though the FEC block size is changed.

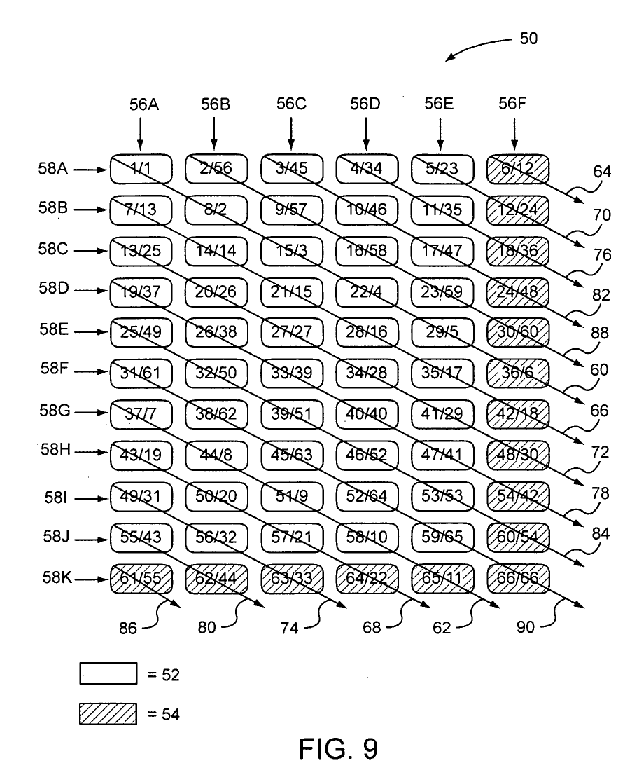

FIG. 9 is a block diagram of an exemplary FEC block 50 showing a plurality of media packets 52 and FEC packets 54 in a 5×10 FEC matrix according to one embodiment of the invention. For purposes of illustration, both media packets 52 and FEC packets 54 may be referred to collectively herein as packets 52, 54. Note that for purposes of defining the L and D dimensions of an FEC matrix, only media packets 52 are considered. In this particular FEC block 50, there are fifty media packets 52 and 16 FEC packets 54 shown in columns 56A-56F and rows 58A-58K. Notably, if the original rate required to send the 50 media packets 52 without any FEC packets 54 is two megabits per second (Mb/s), the increased bandwidth required to send the 50 media packets 52 and the additional 16 FEC packets 54 is 2.64 Mb/s, which represents a 32% error correction bandwidth overhead.

In a conventional FEC block 50, the 16 FEC packets 54 are sufficient to correct a sequential packet loss of six media packets 52 (L (5)+1). Note that in FIG. 9 each packet 52, 54 bears two numbers, a leftmost number separated by a “/” from a rightmost number. For each media packet 52, the leftmost number represents a packet sequence number of the order in which the media packets 52 are sequentially decoded for display on a CPE 26. For each FEC packet 54, the leftmost number represents the sequential order in which the FEC packet 54 would typically be intermixed with sequentially ordered media packets 52. Each FEC packet 54 at the end of each row of the FEC block 50 (column 56F) can be used to correct or recover any media packet 52 that resides in the same row as the FEC packet 54 so long as the other media packets 52 in that row were not lost, or can be recreated using column FEC packets 54. Each FEC packet 54 at the end of each column of the FEC block 50 (row 58K) can be used to correct any single media packet 52 that resides in the same column as the FEC packet 54 so long as the other media packets 52 in that column were not lost, or can be recreated using a row FEC packet 54.

The rightmost number in each packet 52, 54 represents an interleaved packet transmission order according to one embodiment of the invention. By interleaving the packets 52, 54 prior to transmission over a network segment, the present invention increases the number of sequential media packets 52 that may be recovered from L+1=6 sequential packets to L+D+1=16 sequential packets. Notably, in the FEC block 50 shown in FIG. 9, the ability to recover 16 sequential lost packets represents a 167% increase over a conventional FEC block 50. The interleaved order of packets 52, 54 according to one embodiment of the invention is as follows. The first media packet 52, 54 in interleaved order is the media packet 52 at row 58A and column 56A. The next packet 52, 54 in interleaved order is the media packet 52 at row 58B and column 56B. The third packet 52, 54 in interleaved order is the media packet 52 at row 58C and column 56C. The process continues along a diagonal path 60 until the FEC packet 54 at row 58F and column 56F is put in interleaved order. At this point, since column 56F is the last column in the FEC block 50, the next column in interleaved order is the first column, column 56A. However, since row 58F is not the final row in the FEC block 50, the next row in interleaved order is row 58G. Thus, the next media packet 52, 54 in interleaved order is the media packet 52 at row 58G and column 56A. The process continues along a diagonal path 62 until the FEC packet 54 at row 58K and column 56E is put in interleaved order. At this point, since row 58K is the last row in the FEC block 50, the next row in interleaved order is the first row, row 58A. However, since column 56E is not the final column in the FEC block 50, the next column in interleaved order is column 56F. Thus, the next media packet 52, 54 in interleaved order is the FEC packet 54 at row 58A and column 56F as shown by a diagonal path 64. Note that column 56F is the last column in FEC block 50, so the next media packet 52, 54 in interleaved order is the media packet 52 at row 58B and column 56A. This process continues in the same manner as illustrated by diagonal paths 66-90 until all the packets 52, 54 are in interleaved order.

After receipt of the interleaved packets 52, 54 by a downstream service node such as the MSO 20, the MSO 20 arranges the interleaved packets 52, 54 in sequential order as represented by the leftmost number associated with each packet 52, 54 in FIG. 9. Assume that a cable cut occurred during the transmission of the FEC block 50 to the MSO 20, and during the switchover to a backup MHE 10, a number of sequential packets 52, 54 were lost.

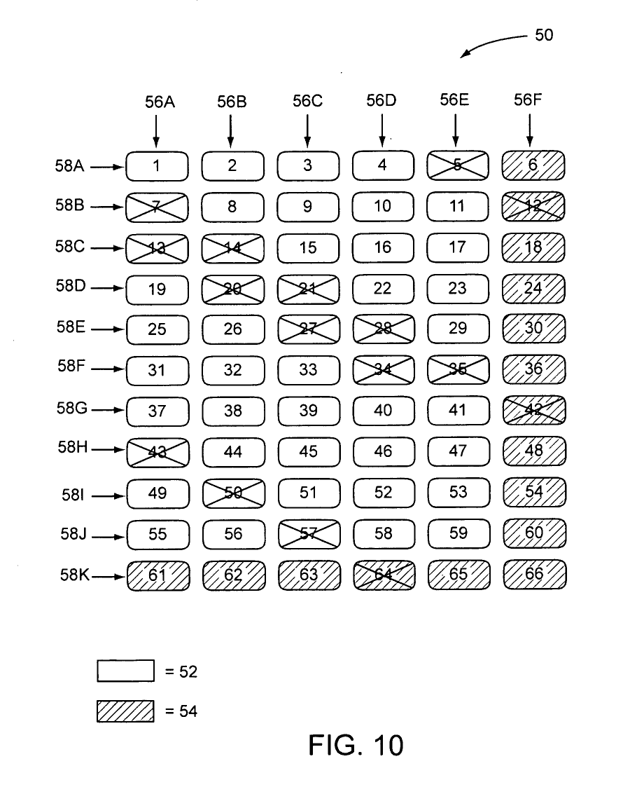

FIG. 10 is a block diagram of the FEC block 50 illustrated in FIG. 9 after receipt and arrangement in sequential order by the MSO 20. The packets 52, 54 bearing an “X” represent lost media packets. Note that sixteen media packets 52, 54 were lost due to the cable cut. Note further that the lost packets 52, 54 are not in sequential order in FIG. 10 because they were transmitted in an interleaved order. Because the present invention interleaved the transmission order of the packets 52, 54, each of the sixteen lost packets 52, 54 can be recovered. For purposes of clarity while discussing the recovery of lost packets, each lost packet will be identified by the number the respective lost packet bears in FIG. 10. Each of the lost packets 5, 42, 43, 50, 57, and 64 may first be recovered by either the respective FEC packet 54 in the associated row or, in the case of lost packet 42, by recreating the lost packet 42 from the existing packets in row 58G.

Lost packets 35 and 12 can next be recovered as the only packets that do not exist in the respective columns 56E and 56F, since packets 5 and 42 were recovered previously. Lost packet 34 can then be recovered as the only packet that does not exist in row 58F, since lost packet 35 was previously recovered. Lost packet 26 can then be recovered since lost packet 26 will be the only packet that does not exist in column 56D after lost packet 34 is recovered. Lost packets 27, 21, 20, 14, 13, and 7 are recovered in similar manner.

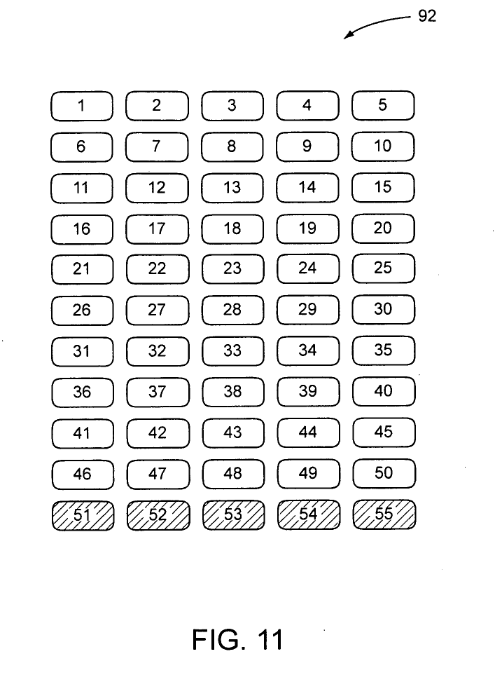

FIG. 11 is a block diagram of a FEC block 92 according to another embodiment of the invention. Assume that the MSO 20 received the FEC block 50 illustrated in FIG. 10 and recovered all lost packets. Further assume that the access network segment 16 does not have sufficient bandwidth to incur the 32% overhead which would be required to include both row and column FEC packets 54 with the FEC block 50. Moreover, assume the loss profile associated with the access network segment 16 indicates that the average sequential packet loss is five or fewer sequential packets. According to one embodiment of the present invention, the MSO 20 may prune, or drop, the row FEC packets 54 from the FEC block 50 and reuse the column FEC packets 54 to create the FEC block 92 illustrated in FIG. 11. Note that the five column FEC packets 54 will be sufficient to recover the typical number of lost packets according to the loss profile associated with the access network segment 16. Notably, the column FEC packets 54 did not need to be regenerated from the FEC matrix, but were reused, reducing processing time and decreasing visible artifacts on a CPE 26 that may be caused by processing delay.

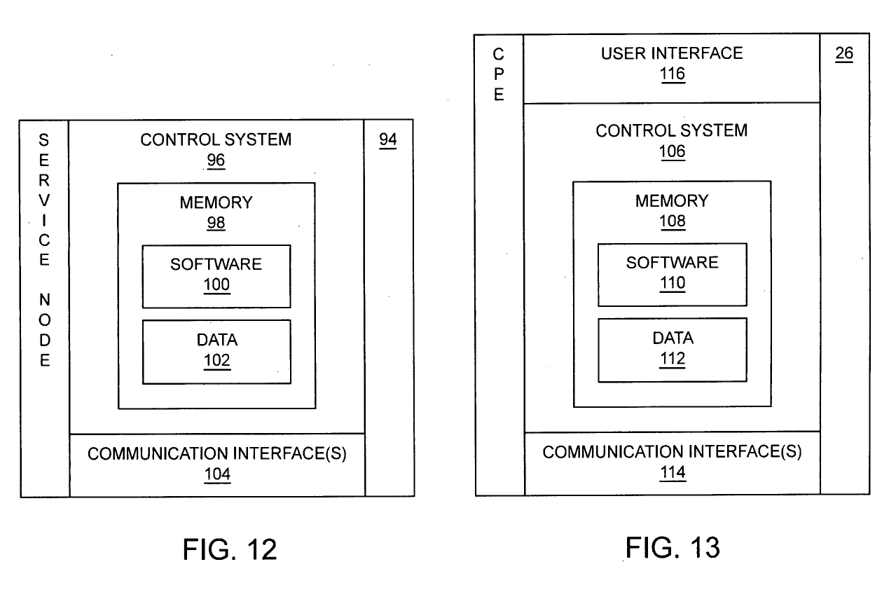

With reference to FIG. 12, a block representation of a service node 94 is provided. The service node 94 is a generic control entity that may provide the functionality of the MSO 20, the MHE 10, the MHO 18, or the PG 24. In particular, the service node 94 may include a control system 96 with sufficient memory 98 for requisite software 100 and data 102 to facilitate operation as described above. In addition to providing the functionality of the overall device, the software 100 may provide the MA 38 and the EEC 36, depending on the configuration. Further, the control system 96 may be associated with one or more communication interfaces 104 to facilitate communications as necessary for operation. The service node 94 may be a stand alone entity or may be part of another element such as a switch, a router, or the like.

With reference to FIG. 13, a block representation of a CPE 26 is illustrated. The CPE 26 may include a control system 106 with sufficient memory 108 for requisite software 1 10 and data 112 to operate as described above. Again, the software 110 may provide the functionality of the CPE 26 in general, as well as the MA 38 and the EEC 36, depending on the configuration. The control system 106 may be associated with one or more communication interfaces 114 to facilitate communications as described above. Further, the control system 106 may be associated with a user interface 116 to facilitate interactions with a customer as well as provide streaming media in an audible or viewable format to the customer as well as receive information from the customer.

Those skilled in the art will recognize improvements and modifications to the preferred embodiments of the present invention. All such improvements and modifications are considered within the scope of the concepts disclosed herein and the claims that follow.

What is claimed is:

1. A method for delivering a plurality of media packets in a switched digital video network from a head end to a customer premises apparatus through a video serving office and a residential gateway, the method comprising:
receiving at the video serving office a first plurality of video packets;
providing first error correction on the first plurality of video packets using a first error correction process;
sending a second plurality of video packets comprising the first plurality of video packets via the switched digital video network to the residential gateway; and
providing second error correction on the second plurality of video packets using a second error correction process at the residential gateway, wherein the first error correction process is different from the second error correction process.

2. The method of claim 1 wherein the second plurality of video packets further comprises a plurality of video packets that were recovered by the first error correction process.

3. The method of claim 1 further comprising receiving a first plurality of forward error correction (FEC) packets associated with the first plurality of video packets, and wherein the first error correction process uses the first plurality of FEC packets to provide the first error correction.

4. The method of claim 3 further comprising sending a second plurality of FEC packets associated with the second plurality of video packets to the residential gateway, and wherein the second error correction process uses the second plurality of FEC packets to provide the second error correction.

5. The method of claim 4 wherein the second plurality of FEC packets is a subset of the first plurality of FEC packets.

6. The method of claim 5 further comprising:
receiving, at the video serving office, an indication that the second plurality of FEC packets is an insufficient number of FEC packets;
receiving a third plurality of video packets at the video serving office;
providing first error correction on the third plurality of video packets using the first error correction process;
sending a fourth plurality of video packets comprising the third plurality of video packets via the switched digital video network to the residential gateway; and
in response to the indication, sending a third plurality of FEC packets associated with the fourth plurality of video packets via the switched digital video network to the residential gateway, and wherein the fourth plurality of FEC packets comprises a greater number of FEC packets than the second plurality of FEC packets.

7. The method of claim 1 wherein the first error correction process is a forward error correction (FEC) error correction process using a first plurality of row FEC packets and a first plurality of column FEC packets, and wherein the second error correction process is an FEC error correction process using only a second plurality of column FEC packets.

8. The method of claim 7 wherein the second plurality of column FEC packets comprises the first plurality of column FEC packets.

9. The method of claim 1 wherein the first error correction process is a forward error correction (FEC) error correction process, and wherein the second error correction process is an automatic repeat request (ARQ) error correction process.

10. The method of claim 1 wherein the first error correction process is selected based on a loss profile associated with a network segment to which the video serving office is coupled.

11. A method for sending a first plurality of video packets through a network having a core network segment and an access network segment, the core network segment coupled to the access network segment with a first service node, and the access network segment coupled to a local network segment with a second service node, comprising:
generating a first plurality of forward error correction (FEC) packets based on the first plurality of video packets;
sending the first plurality of video packets and the first plurality of FEC packets to the first service node;
removing a second plurality of FEC packets from the first plurality of FEC packets to form a third plurality of FEC packets; and
sending the first plurality of video packets and the third plurality of FEC packets to the second service node, wherein the core network segment has a first bandwidth that is greater than a second bandwidth of the access network segment.

12. The method of claim 11 further comprising:
receiving, from the second service node, an indication that the third plurality of FEC packets comprises an insufficient FEC quantity of FEC packets;
receiving a second plurality of video packets;
sending the third plurality of video packets to the second service node; and
in response to the indication, sending a fourth plurality of FEC packets associated with the third plurality of video packets to the second service node, the fourth plurality of FEC packets comprising a quantity of FEC packets greater than the insufficient FEC quantity of FEC packets.

13. The method of claim 11 further comprising:
receiving, at the first service node, an indication that the third plurality of FEC packets is an insufficient number of FEC packets; and
in response to the indication, sending a fourth plurality of FEC packets to the second service node, and wherein the fourth plurality of FEC packets comprises a greater number of FEC packets than the third plurality of FEC packets.

14. A method for providing error correction over two network segments having different bandwidths comprising:
receiving, at a first service node, a first plurality of data packets comprising a first plurality of video packets and a first plurality of forward error correction (FEC) packets, each of the first plurality of data packets having an associated sequence number identifying a sequential order associated with the first plurality of data packets, and wherein the first plurality of data packets are received in an interleaved order at the first service node; and
sending to a second service node a second plurality of data packets comprising the first plurality of video packets and a second plurality of FEC packets, the second plurality of FEC packets comprising a proper subset of the first plurality of FEC packets, the second plurality of data packets being sent in a sequential order based on a sequence number associated with each of the first plurality of video packets and the second plurality of FEC packets.

15. A service node comprising:
an input first interface adapted to communicate with a first network segment;
an output interface adapted to communicate with a second network segment; and
a control system coupled to the input first interface and the output interface and adapted to:
receive a first plurality of video packets and a first plurality of error correction packets associated with the first plurality of video packets via the first network segment;
provide first error correction on the first plurality of video packets using the first plurality of error correction packets;
generate a second plurality of error correction packets based on the first plurality of video packets; and
send a second plurality of video packets comprising the first plurality of video packets and the second plurality of error correction packets to a second service node.

16. The service node of claim 15 wherein the second plurality of video packets further comprises a plurality of recovered video packets that were recovered by the first error correction.

17. The service node of claim 15 wherein the second plurality of error correction packets is a proper subset of the first plurality of error correction packets.

18. The service node of claim 17 wherein the first plurality of error correction packets comprises a plurality of row error correction packets and a plurality of column error correction packets, wherein the second plurality of error correction packets consists of the plurality of column error correction packets.

19. The service node of claim 15 wherein the control system is further adapted to:
receive an indication that the second plurality of error correction packets is an insufficient number of error correction packets;
receive a third plurality of video packets and a third plurality of error correction packets;
send a fourth plurality of video packets comprising the third plurality of video packets to the second service node; and
in response to the indication, send a fourth plurality of error correction packets associated with the fourth plurality of video packets to the second service node, and wherein the fourth plurality of error correction packets comprises a greater number of error correction packets than the insufficient number of error correction packets.

20. The service node of claim 15 wherein the first error correction is selected based on a loss profile associated with the first network segment.

21. A method for delivering a plurality of media packets in a switched digital video network having a first service node coupled to a second service node via a first network segment and the second service node coupled to a third service node via a second network segment, the method comprising:
receiving at the second service node via the first network segment a first plurality of video packets from the first service node;
providing first error correction on the first plurality of video packets using a first error correction process at the second service node;
sending a second plurality of video packets comprising the first plurality of video packets to the third service node via the second network segment; and
providing second error correction on the second plurality of video packets using a second error correction process at the third service node, wherein the first error correction process is different from the second error correction process.

22. The method of claim 21 further comprising receiving a first plurality of forward error correction (FEC) packets associated with the first plurality of video packets, and wherein the first error correction process uses the first plurality of FEC packets to provide the first error correction.

23. The method of claim 22 further comprising sending a second plurality of FEC packets associated with the second plurality of video packets to the third service node, and wherein the second error correction process uses the second plurality of FEC packets to provide the second error correction.
